(19) United States
(12) Patent Application Publication
(10) Pub. No.: US 2017/0285102 A1
(43) Pub. Date: Oct. 5, 2017

(54) IC TEST SITE VISION ALIGNMENT SYSTEM

(71) Applicant: Delta Design, Inc., Poway, CA (US)

(72) Inventors: Kexiang Ken DING, San Diego, CA (US); Larry STUCKEY, Poway, CA (US); James FRANDSEN, Ramona, CA (US); Samer KABBANI, Encinitas, CA (US); Michael Anthony LAVER, El Cajon, CA (US)

(73) Assignee: Delta Design, Inc., Poway, CA (US)

(21) Appl. No.: 15/472,006

(22) Filed: Mar. 28, 2017

Related U.S. Application Data
(60) Provisional application No. 62/314,482, filed on Mar. 29, 2016.

(51) Int. Cl. G01R 31/28; G01R 1/073

(52) U.S. Cl. CPC G01R 31/2891; G01R 1/07314

(57) ABSTRACT

A vision alignment system for a test handler system includes a transfer mechanism that transfers a device from an input side to a test side, a contactor array positioned at the test side, and a pick-and-place device that moves the device from the transfer mechanism to the contactor array. An engagement mechanism on the pick-and-place device engages with alignment devices on the transfer mechanism and contactor array. To avoid positioning the vision alignment system in the test side, a first vision mechanism is positioned away from the test socket and determines the position of the device in a common local coordinate system, a second vision mechanism is positioned at an output side and determines a position of the contactor array in the local coordinate system, and the correction mechanism corrects a position of the device based on an offset between the positions in the coordinate system.

### CROSS-REFERENCE TO RELATED APPLICATIONS

The present application claims priority to U.S. Provisional Application No. 62/314,482, filed on Mar. 29, 2016, which is hereby incorporated by reference in its entirety.

### FIELD

The present disclosure generally relates to a vision alignment system for an integrated circuit (“IC”) device test handler system. In particular, the present disclosure relates to a vision alignment system utilizing a coined pattern and a correction mechanism to perform an IC device alignment process.

### BACKGROUND

When testing an IC device, a contactor array having a contactor pin array is used to engage with the contact array of the IC device to electrically test the IC device. For successful testing, the contact array of the IC device must be accurately aligned with the contactor pin array to ensure that all contactor pins engage with corresponding contacts on the IC device. Existing alignment systems used to test IC devices may use a mechanical alignment system at the test side without the use of vision systems. However, mechanical alignment systems may not be as accurate or precise due to tolerances present in the mechanical system. In addition, existing vision alignment systems often need to utilize space for vision systems and alignment correction mechanisms in the test side region, in which limited space is available. Moreover, these systems often require continual, runtime adjustment of the IC device during testing, effecting handling time and runtime speed of the testing procedure.

### SUMMARY

A vision alignment system and method addresses the need for a vision alignment system that can accurately and precisely perform alignment of an IC device without utilizing the limited space available in the test side region and without impacting handling time and runtime speed during testing of the IC device.

In one embodiment, a vision alignment system for an integrated circuit device test handler system includes a transfer mechanism, a contactor array, a test pick-and-place device, a first vision mechanism, a second vision mechanism, and a correction mechanism. The transfer mechanism is configured to transfer an integrated circuit device from an input side to a test side of the test handler system and includes a first alignment device. The contactor array is positioned at the test side and configured to electrically test the integrated circuit device. The contactor array includes a second alignment device. The test pick-and-place device is configured to move the integrated circuit device from the transfer mechanism to the contactor array and includes a first engagement mechanism configured to engage with the first alignment device and the second alignment device. The first vision mechanism is positioned at the input side and configured to determine a position of the integrated circuit device relative to a common local coordinate system. The second vision mechanism is positioned at an output side of the test handler system and configured to determine a position of the contactor array relative to the common local coordinate system. The correction mechanism is configured to correct a position of the integrated circuit device placed on the transfer mechanism based on a calculated offset between the position of the integrated circuit device and the position of the contactor array in the common local coordinate system.

In one aspect, an engagement between the first engagement mechanism of the test pick-and-place device and the first alignment device of the transfer mechanism and an engagement between the first engagement mechanism of the test pick-and-place device and the second alignment device of the contactor array define the common local coordinate system among the test pick-and-place device, the transfer mechanism, the contactor array, and the correction mechanism.

In one aspect, the first vision mechanism is mounted on the transfer mechanism.

In one aspect, the first vision mechanism is configured to image the test pick-and-place device as the transfer mechanism moves from the test side to the input side of the test handler system.

In one aspect, the test pick-and-place device further includes a second engagement mechanism. The first engagement mechanism defines an origin of the common local coordinate system and the second engagement mechanism defines a rotation in the common local coordinate system.

In one aspect, the transfer mechanism further includes a third alignment device. The first alignment device is a first pin configured to engage with the first engagement mechanism and the third alignment device is a second pin configured to engage with the second engagement mechanism.

In one aspect, the first engagement mechanism is a first bushing mounted on a head of the test pick-and-place device and the second engagement mechanism is a second bushing mounted on the head of the pick-and-place device.

In one aspect, the first bushing includes a main body and an origin-establishing extension that extends from the main body and includes a central groove in the form of a half circle.

In one aspect, the second bushing includes a main body and a rotation-establishing extension that extends from the main body and includes a flat surface.

In one aspect, the test pick-and-place device further includes a first fiducial positioned between the first bushing and a first side of the integrated circuit device when mounted on the test pick-and-place device and a second fiducial positioned between the second position and a second side of the integrated circuit device.

In one aspect, the integrated circuit device is a ball grid array device.

In one aspect, the transfer mechanism includes a device pocket comprising a hole grid array formed on a bottom surface of the device pocket, the hole grid array being configured to receive the ball grid array device.

In one aspect, the transfer mechanism further includes a vacuum system configured to apply a vacuum pressure to the hole grid array such that the ball grid array device is precisely aligned in the hole grid array.

In one aspect, the vacuum system is configured to detect when a pressure threshold is reached after applying the vacuum pressure to the hole grid array.

In one aspect, the device pocket further includes chamfered edges formed peripherally along an upper portion of the device pocket, the chamfered edges being angled such that placement of the integrated circuit device in the device pocket is facilitated by the chamfered edges.

In one aspect, the correction mechanism is configured to correct the position of the integrated circuit device by adjusting positions of the first pin and the second pin.

In one aspect, the vision alignment system further includes an input pick-and-place device and an input vision mechanism. The input pick-and-place device is configured to place the integrated circuit device on the transfer mechanism, and the input vision mechanism is configured to determine a position of the integrated circuit device relative to the input pick-and-place device and correct a placement of the integrated circuit device on the transfer mechanism.

In one aspect, the correction mechanism includes a plurality of actuators configured to correct the position of the integrated circuit device placed on the transfer mechanism as the transfer mechanism transfers the integrated circuit device from the input side to the test side.

In one aspect, the correction mechanism includes a micro-alignment system. The micro-alignment system includes a head guiding ring and a socket apparatus. The head guiding ring is configured to be attached to the test pick-and-place device. The socket apparatus includes a fixed mounting frame having an opening in which the contactor array is locatable, a moveable socket guiding ring having an opening in which the head guiding ring is locatable, and a plurality of actuators configured to move the moveable socket guiding ring relative to the fixed mounting frame. The socket apparatus is configured to adjust a position of the head guiding ring by moving the moveable socket guiding ring while the head guiding ring is located in the opening of the moveable socket guiding ring to align the integrated circuit device to the contactor array.

In another embodiment, a method for visually aligning an integrated circuit device in a test handler system includes moving an integrated circuit device using a transfer mechanism from an input side of the test handler system to a test side of the test handler system, the transfer mechanism comprising a first alignment device. The method further includes moving the integrated circuit device from the transfer mechanism to a contactor array using a pick-and-place device, the test pick-and-place device comprising a first engagement mechanism. The method further includes imaging the integrated circuit device on the pick-and-place device and calculating a position of the integrated circuit device relative to a local coordinate system. The method further includes testing the integrated circuit device using the contactor array, the contactor array comprising a second alignment device and the tested integrated circuit device having a plurality of test markings. The method further includes imaging the tested integrated circuit device at an output side of the test handler system, calculating a position of the contactor array relative to the local coordinate system based on positions of the plurality of test markings and the relative position of the integrated circuit device, determining an offset between the calculated position of the integrated circuit device and the calculated position of the contactor array relative to the local coordinate system, and correcting a position of the integrated circuit device placed on the transfer mechanism based on the determined offset using a correction mechanism.

In one aspect, an engagement between the first engagement mechanism of the pick-and-place device and the first alignment device of the transfer mechanism and an engagement between the first engagement mechanism of the pick-and-place device and the second alignment device of the contactor array define the local coordinate system among the pick-and-place device, the transfer mechanism, the contactor array, and the correction mechanism.

In one aspect, the method further includes monitoring a change in the position of the integrated circuit device placed on the transfer mechanism during a testing of the integrated circuit device, and correcting the change in the position of the integrated circuit device placed on the transfer mechanism.

In one aspect, the integrated circuit device is a ball grid array device.

In one aspect, the transfer mechanism includes a device pocket having a hole grid array at a bottom surface configured to receive the ball grid array device.

### BRIEF DESCRIPTION OF THE DRAWINGS

FIG. 1A is a schematic, top plan view of a device test handler system having a vision alignment system according to an embodiment of the present invention.

FIG. 1B is a schematic, perspective view of the test handler system of FIG. 1A.

FIG. 2A is a perspective view of a head for a test pick-and-place device for the test handler system of FIG. 1A.

FIG. 2B is a bottom view of the head of the test pick-and-place device of FIG. 2A.

FIG. 3A is a perspective view of a first engagement mechanism for the test pick-and-place device of FIGS. 2A-2B.

FIG. 3B is a perspective view of a second engagement mechanism for the test pick-and-place device of FIGS. 2A-2B.

FIG. 4A is a top view of a transfer mechanism for the test handler system of FIG. 1A.

FIG. 4B is a perspective view of a device pocket for the transfer mechanism of FIG. 4A.

FIG. 4C is a side sectional view of the device pocket of FIG. 4B.

FIG. 5 is a perspective view of a vision mechanism for an input side of the test handler system of FIG. 1A.

FIG. 6 is a partial perspective view of a bottom side of an input side pick-and-place device for the test handler system of FIG. 1A.

FIG. 7 is a perspective view of a vision mechanism for a transfer mechanism for the test handler system of FIG. 1A.

FIG. 8 is a perspective view of a vision mechanism for an output side of the test handler system of FIG. 1A.

FIG. 9 is a schematic, plan view of a correction mechanism for the test handler system of FIG. 1A.

FIG. 10 is a flowchart showing a process for aligning a device using the vision alignment system of FIG. 1A.

FIG. 11 is a bottom view of a device having test markings after being subjected to electrical testing using the test handler system of FIG. 1A.

FIG. 12 is a schematic view comparing an expected linear movement with an imaged non-linear movement of actuators used in the test handler system of FIG. 1A.

FIGS. 13A-13F are schematic, cross-sectional views of a process for aligning a device using a vision alignment system according to another embodiment of the present invention.

FIG. 14 is a top view of a device pocket of a transfer mechanism using the alignment process of FIGS. 13A-13F.

FIG. 15 is a perspective view of a correction mechanism for the test handler system of FIG. 1A according to another embodiment of the present invention.

FIGS. 16A-16B are perspective views of the correction mechanism of FIG. 15.

### DETAILED DESCRIPTION

Embodiments of the present invention will be described below with reference to the accompanying drawings. It would be understood that the following description is intended to describe exemplary embodiments of the invention, and not to limit the invention.

Referring generally to the figures, the present disclosure provides for a vision alignment system for an IC test handler system that can precisely align a device to a contactor array for testing. The system minimizes equipment needed in the test side by establishing a local coordinate system based on an engagement between a test pick-and-place device and a transfer mechanism and contactor array of the test handler system with, in some embodiments, a pin-bushing engagement. The defined local coordinate system allows for offset determination and subsequent alignment correction to occur offline and away from the test side region. This local coordinate system may serve as a common reference in determining relative positions between the device and the contactor array. Vision mechanisms on an output side of the test handler system may be used to measure and locate the contactor array within the local coordinate system. Vision mechanisms on an input side, which may be positioned on the transfer mechanism, may be used to measure and locate the device within the local coordinate system. Positions of each device may be then used to determine the relative offset between the device and the contactor array in terms of the local coordinate system. A correction mechanism may then be used to correct the position of the device until the offset is reduced to within tolerance. Once this is accomplished, the shuttle pocket of the device transfer mechanism may be locked in place, matching (or “coining”) the device to the contactor array for testing purposes. The alignment process may be performed during a calibration process of the test handler system without a need to continually adjust alignment during runtime of the test handler system, thus reducing overall runtime handling of the device.

### The Test Handler System

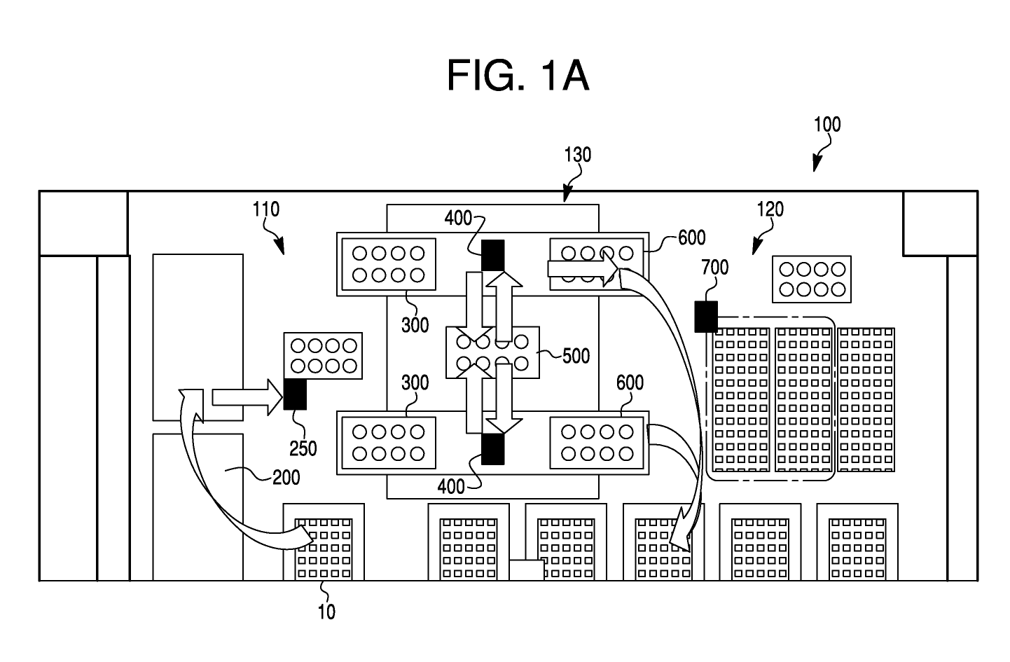

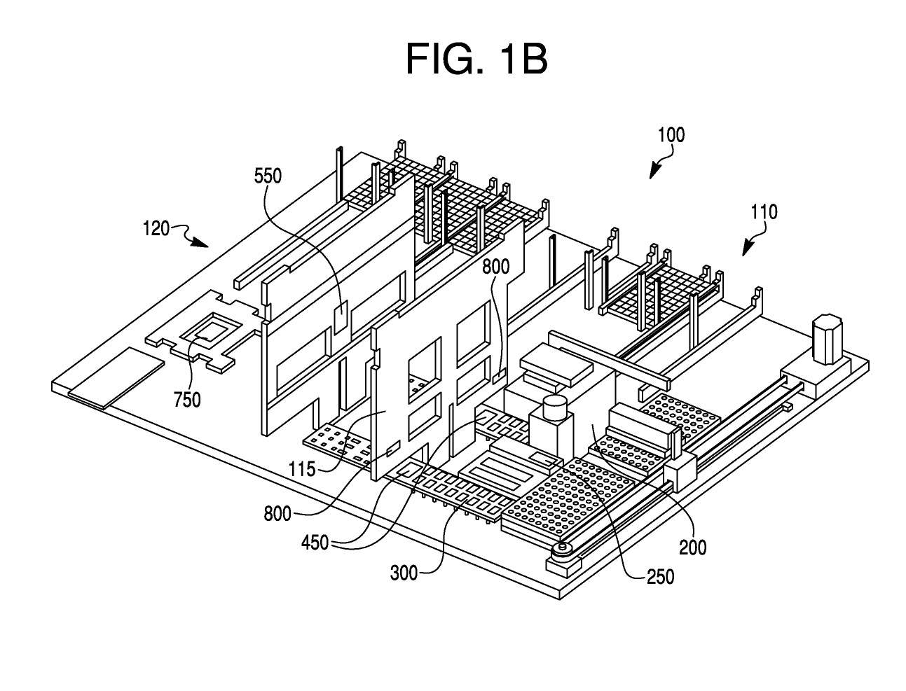

FIGS. 1A and 1B show a test handler system having a vision alignment system according to an embodiment of the present invention. The test handler system 100 is configured to electrically test a contact array of a device 10, which may be an IC device, such as a ball grid array (“BGA”) device or a land grid array (“LGA”) device. For illustration purposes, reference will be made to a BGA device 10 in the description below. However, the present disclosure is not limited to this type of device and may apply to other IC devices.

As shown in FIGS. 1A-1B, the test handler system 100 generally includes an input side 110, an output side 120, and a test side 130, which is positioned between the input side 110 and the output side 120. During a testing procedure of a device 10, an input pick-and-place device (“IPnP”) 200 picks up a device 10 from the input side 110 and places the device 10 in one or more input-side transfer mechanisms 300, which may be shuttles configured to hold a plurality of devices 10 for testing. The input-side transfer mechanism 300 is configured to move the devices 10 from the input side 110 to the test side 130, where one or more test pick-and-place devices (“TSPnP”) 400 pick up a device 10 from the input-side transfer mechanism 300 and moves the device 10 to a contactor array 500 positioned in a region of the test side 130. At the contactor array 500, the TSPnP 400 plunges the device 10 into the contactor array 500. When inserted into the contactor array 500, the contact array of the device 10 is electrically tested with the use of, for example, a plurality of pogo pins (not shown) that individually press into the BGA present on the device 10 to test the contacts. In order to ensure proper testing of the BGA device 10, it is important that each pogo pin engages with a corresponding ball in the BGA of the device 10.

Once tested, the TSPnP 400 removes the device 10 from the contactor array 500 and transfers the tested device 10 to one or more output-side transfer mechanisms 600. Like the input-site transfer mechanism 300, the one or more output-site transfer mechanisms 600 may be shuttles configured to hold a plurality of devices 10. The output-site transfer mechanism 600 is configured to transfer the tested devices 10 from the test side 130 to the output side 120, where an output pick-and-place device (“OPnP”) 700 picks up the tested devices 10 from the output-side transfer mechanism 600 and places the tested device on a tested device tray for further processing.

### The Vision Alignment and Correction System

As will be described in further detail below, the vision alignment system is added to the test handler system 100 described above in a minimal way and is configured to operate during a calibration process in order to coin the position of the device 10 to the position of the contactor array 500 for accurate and precise testing during the runtime of the test handler system 100.

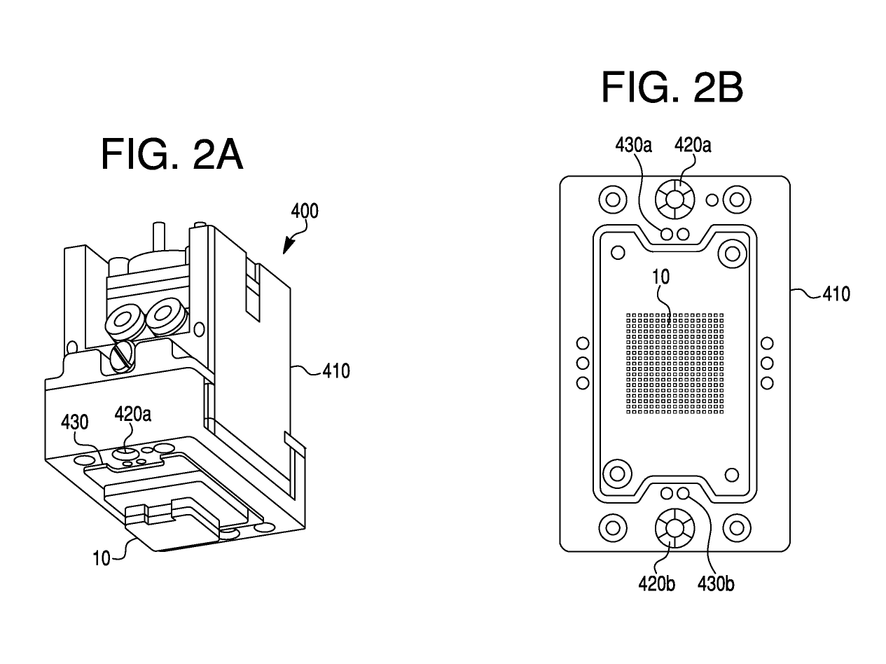

FIGS. 2A-2B show a head 410 of the TSPnP 400 that incorporates the vision alignment system according to an embodiment of the present invention. As shown in the figures, the TSPnP 400 is configured to define a two-dimensional TSPnP coordinate system (e.g., X-Y coordinate system). Because the TSPnP 400 acts as a link between the device 10 and the contactor array 500, the TSPnP coordinate system defined by engagement mechanisms (e.g., bushings or sleeves) on the head 410 of the TSPnP 400 may serve to define a common local coordinate system among the input-side transfer mechanism 300 and the contactor array 500 through an engagement with the input-side transfer mechanism 300 and the contactor array 500. This common local coordinate system may be used as a reference to precisely align the device 10 to the contactor array 500.

As shown in FIGS. 2A-2B, a bottom surface of a head 410 of the TSPnP 400 is configured to pick up a device 10 and move the device 10 to a desired position within the test handler system 100. As shown in FIG. 2B, the head 410 includes a first engagement mechanism 420a, which may be, for example, a first bushing 420a, positioned relative to a first side of the device 10, and a second engagement mechanism 420b, which may be, for example, a second bushing 420b, positioned relative to a second side of the device 10, which is opposite to the first side of the device 10. Positioned within an area of the first bushing 420a and located between the first bushing 420a and the first side of the device 10 may be a first fiducial 430a. In addition, positioned within an area of the second bushing 420b and located between the second bushing 420b and the second side of the device 10 may be a second fiducial 430b. The fiducials 430a, 430b may be in the form of markings (e.g., bars or dots), points or other visual objects, which serve to increase image contrast in order to allow the vision mechanism of the vision alignment system (described below) to optically locate the first and second bushings 420a, 420b.

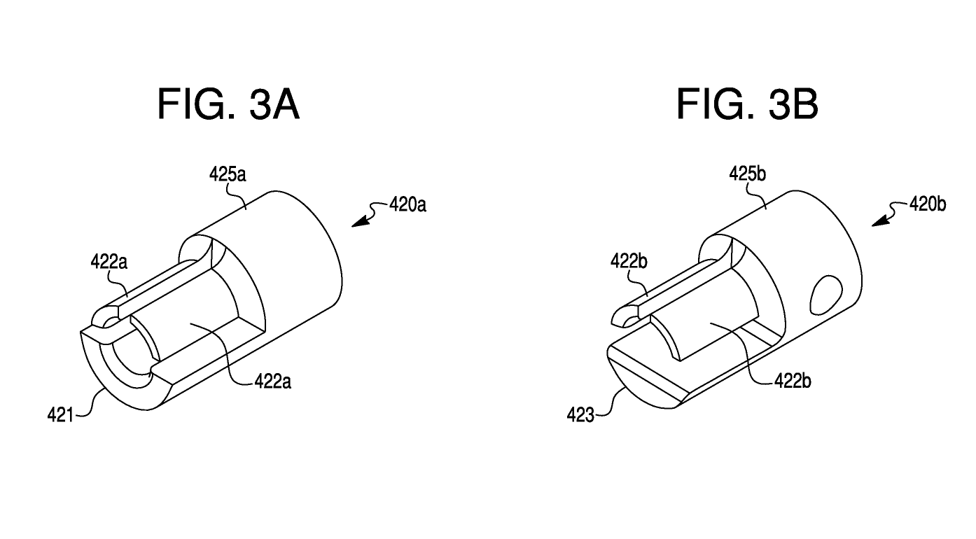

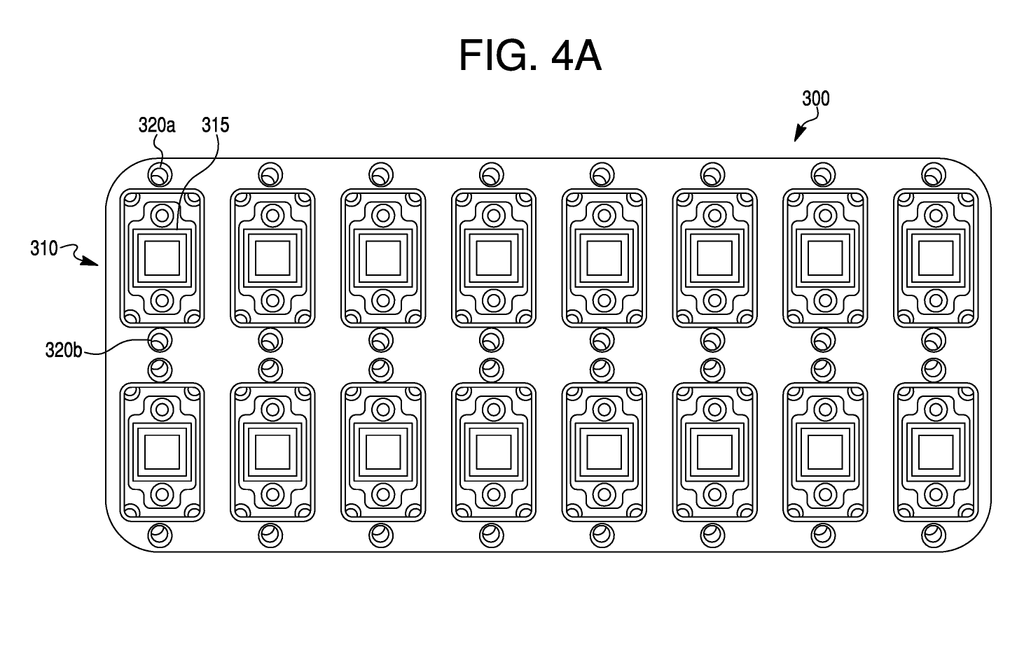

The first bushing 420a and the second bushing 420b are configured to engage with corresponding alignment devices (e.g., pins, dowels, rods) disposed on the input-side transfer mechanism 300 (described below) and corresponding alignment devices disposed on the contactor array 500. In addition, as shown in FIGS. 3A and 3B, the first and second bushings 420a, 420b are used as reference points in establishing the TSPnP coordinate system.

For example, FIG. 3A shows a first bushing 420a that may serve as a first reference point for the TSPnP coordinate system. As shown in FIG. 3A, the first bushing 420a includes a main body 425a from which multiple deflective extensions 422a protrude. The deflective extensions 422a are configured to deflect slightly when the first bushing 420a engages with a corresponding alignment pin. The first bushing 420a further includes an origin-establishing extension 421, which extends from the main body 425a and is opposed to the deflective extensions 422a. The origin-establishing extension 421 is a rigid member that includes a central groove in the form of a half circle, which engages with the corresponding alignment devices of the input-side transfer mechanism 300 and the contactor array 500. The first bushing 420a is configured to serve as the origin reference of the TSPnP coordinate system. Thus, the first bushing 420a, along with the symmetrical center of the fiducial 430a, allows the vision alignment system to determine translational (i.e., X and Y) offsets of the device 10 relative to the TSPnP coordinate system.

The second bushing 420b may serve as a second reference point for the TSPnP coordinate system. As shown in FIG. 3B, the second bushing 420b includes a main body 425b from which multiple deflective extensions 422b protrude. Like the first bushing 420a, deflective extensions 422b are configured to deflect slightly when the second bushing 420b engages with a corresponding alignment device. The second bushing 420b further includes a rotation-establishing extension 423, which extends from the main body 425b and is opposed to the deflective extensions 421b. The rotation-establishing extension 423 is a rigid member that is generally shaped as a half circle having a flat surface that faces the deflective extensions 422b and engages with the corresponding alignment devices of the input-side transfer mechanism 300 and the contactor array 500. The second bushing 420b is configured to serve as the rotation reference of the TSPnP coordinate system. Thus, the second bushing 420b, along with the symmetrical center of the fiducial 430b, allows the vision alignment system to determine rotational (i.e., 0) offsets of the device 10 relative to the TSPnP coordinate system.

In order to reduce clearance between the first and second bushings 420a, 420b and the alignment devices of the input-side transfer mechanism 300 and the contactor array 500, the first and second bushings 420a, 420b are preferably spring-loaded and include a diameter that is smaller than the alignment devices disposed on the input-side transfer mechanism 300 and the contactor array 500. This allows the first and second bushings 420a, 420b to precisely engage with the alignment devices of the input-side transfer mechanism 300 and the contactor array 500 for an accurate determination of the relative position of the device 10 in the TSPnP coordinate system. At the same time, the deflective extensions 422a, 422b allow for the deflection necessary to compensate for the reduced clearance. Accordingly, with the first bushing 420a and the second bushing 420b, along with their corresponding fiducials 430a, 430b, the vision alignment system may determine the relative translation and rotation of the device 10 within the TSPnP coordinate system for alignment correction.

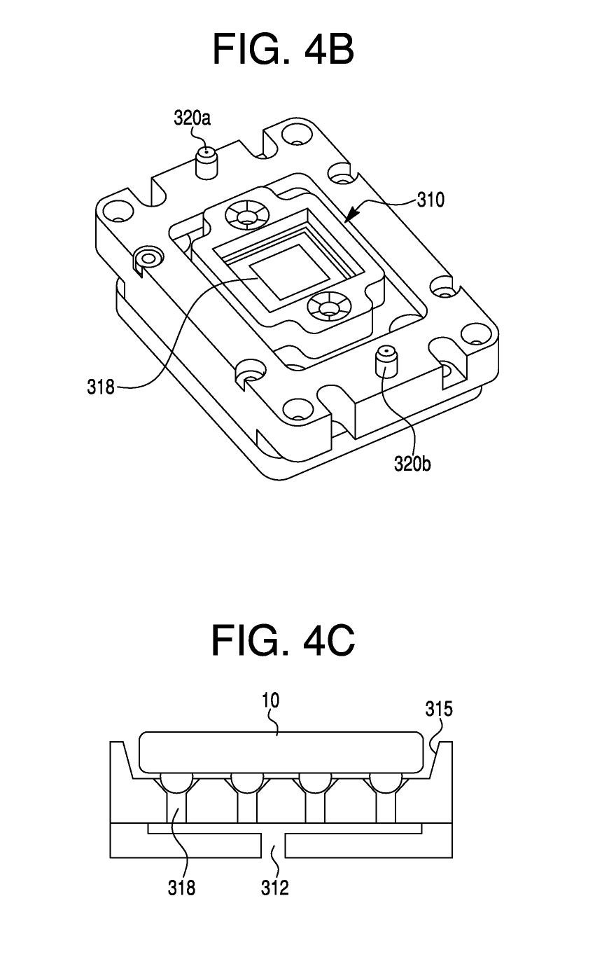

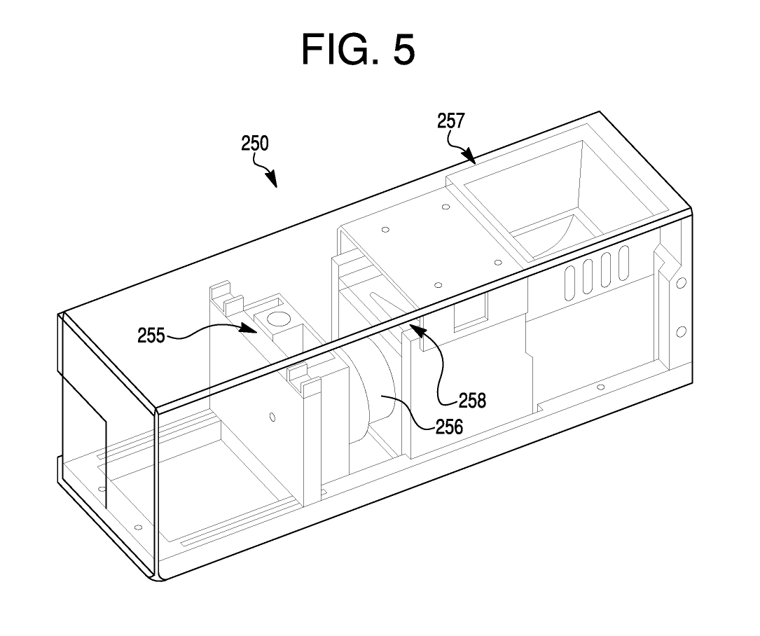

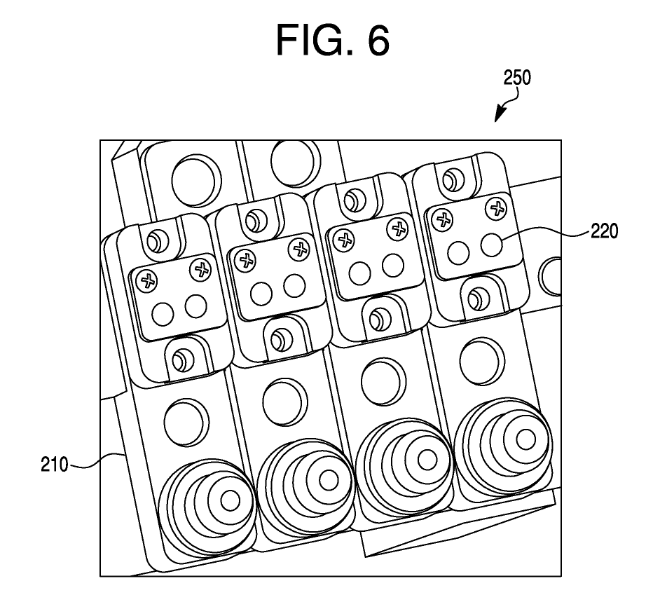

In order to precisely establish the position of the device 10 in relation to the TSPnP coordinate system, the input-side transfer mechanism 300 may be configured to precisely align the device 10 relative to the alignment devices disposed on the input-side transfer mechanism 300. For example, as shown in FIGS. 4A-4C, the transfer mechanism 300 may include a plurality of device pockets 310, each of which are configured to receive and hold a device 10 when being transferred from the input side 110 to the test side 130. As mentioned above, the transfer mechanism 300 includes a plurality of alignment devices for each of the device pockets 310. As shown in FIG. 4A, an alignment device, which may be, for example, a first pin 320a, is disposed at and extends upward from a first side of the device pocket 310 and is configured to engage with the first bushing 420a of the TSPnP 400. An additional alignment device, which may be, for example, a second pin 320b, is disposed at and extends upward from a second side of the device pocket 310, which is opposite the first side, and is configured to engage with the second bushing 420b of the TSPnP 400. Alignment devices similar to those disposed on the input-side transfer mechanism 300 (such as those shown, for example, in FIG. 4B) are also disposed on the contactor array 500 (e.g., third and fourth pins) such that the engagement mechanisms of the TSPnP 400 may similarly engage with the contactor array 500 to define the common local coordinate system.

To facilitate entry of the devices 10 into the device pockets 310, the device pockets 310 include chamfered edges 315 formed peripherally along an upper portion of the device pockets 310. The chamfered edges 315 are angled such that when a device 10 is placed into a device pocket 310 by the IPnP 200, any misalignment of the device 10 may be sufficiently corrected by allowing the device 10 to slide along the chamfered edges 315 toward a bottom surface of the device pocket 310.

The bottom surface of the device pocket 310 includes a hole grid array (“HGA”) 318 formed by a plurality of holes that match the BGA of the device 10. When the device 10 is roughly aligned by the chamfered edges 315, the HGA 318 allows for precise alignment of the device 10 in the device pocket 310 relative to the first and second pins 320a, 320b. To ensure that the device 10 is sufficiently placed within the HGA 318, a vacuum system may be used. For example, as shown in FIG. 4C, the vacuum system may be configured to apply a vacuum pressure 312 at an underside of the device pocket 310. The vacuum pressure 312 pulls the device 10 into the HGA 318 for precise alignment. The vacuum system may be further configured to detect a pressure present at the underside of the device pocket. When a certain pressure threshold is reached, the device 10 is then precisely placed into the device pocket 310.

Although the chamfered edges 315 of the device pocket 310 allow for sufficient alignment of the device 10 into the device pocket 310 for the vacuum system, an input vision alignment system may be incorporated into the vision alignment system. The input vision alignment system may provide a rough alignment placement by the IPnP 200 of the device 10 relative to the device pocket 310 to ensure that the device 10 will be seated into the device pocket 310 by the chamfered edges 315.

For example, as shown in FIGS. 1A and 1B, an input vision mechanism 250 may be positioned to image a device 10 as the IPnP 200 moves the device 10 to the input-side transfer mechanism 300. As shown in FIG. 5, the input vision mechanism 250 may be an up-looking vision mechanism positioned below the IPnP 200 to capture images of a device 10 mounted on the IPnP 200. The input vision mechanism 250 may generally include a side-facing camera 255 and a lens 256 for capturing images of the device 10 mounted on the IPnP 200, a beam splitter 258 and a light house having a prism and programmable angle LED lighting 257 to facilitate image capturing by the camera 255. In addition, as shown in FIG. 6, a head 210 of the IPnP 200 may include one or more fiducials 220 for detection of the device 10 by the input vision mechanism 250.

Because the input vision alignment system only needs to position the device 10 in close proximity to the device pocket 310, the camera 255 of the input vision mechanism 250 may have a lower resolution than other vision mechanisms used in the vision alignment system. In addition, the input vision alignment system may directly use the X-Y gantry of the IPnP 200 to make alignment corrections without the use of actuators present on the IPnP head 210, allowing the input vision alignment system to be made simpler. A vision alignment approach such as an approach described in U.S. Pat. No. 8,773,530, which is incorporated herein by reference in its entirety, may be used to align the device 10 with the device pocket 310.

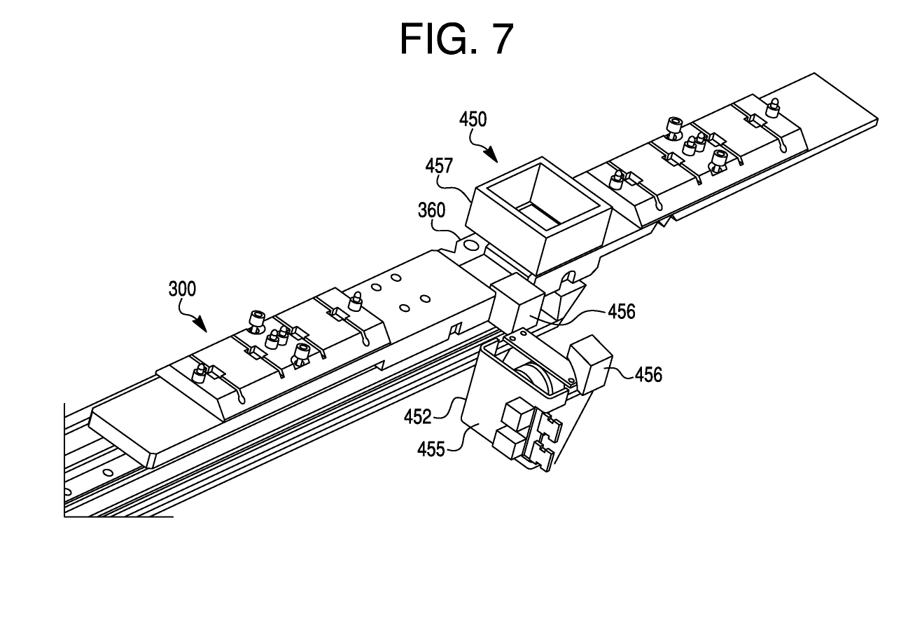

As shown in FIG. 7, to detect the position of the device 10 within the TSPnP coordinate system, a rear-side TSPnP vision mechanism 450 may be used in the vision alignment system. The rear-side TSPnP vision mechanism 450 may be an up-looking vision mechanism mounted to a support portion 360 of one of the one or more input-side transfer mechanisms 300 (e.g., the input-side transfer mechanism 300 positioned at a rear side of the test handler system as shown in FIG. 1A). The rear-side TSPnP vision mechanism 450 may include a frame 452 that holds a side-facing camera 455 for capturing images of the device 10 mounted on the TSPnP head 410 placed at a rear side of the test site 130, and a light house 457 and prisms 456 for facilitating image capturing by the camera 455. In some embodiments, a front-side TSPnP vision mechanism may also be added to one of the one or more input-side transfer mechanisms 300 (e.g., the input-side transfer mechanism 300 positioned at a front side of the test handler system as shown in FIG. 1A) to obtain images of the device 10 on the TSPnP head 410 of the TSPnP 400 positioned at the front side of the test site 130. The front-side TSPnP vision mechanism may be the same as the rear-side TSPnP vision mechanism 450 and may also be utilized to detect the position of the device 10 within the TSPnP coordinate system.

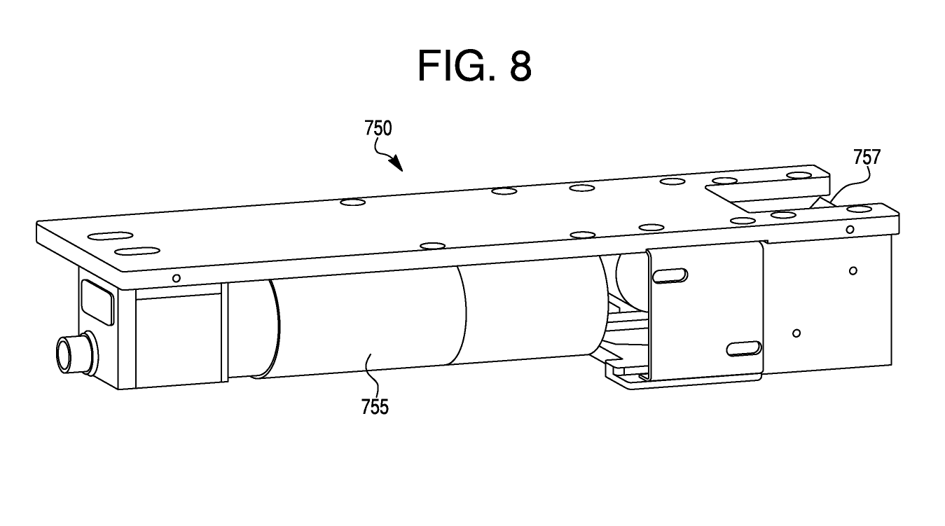

As shown in FIG. 1B, the vision alignment system further includes an OPnP vision mechanism 750 positioned at the output side 120 of the test handler system 100, which is used in determining the position of the contactor array 500 in the TSPnP coordinate system. As shown in FIG. 8, the OPnP vision mechanism 750 may be an up-looking vision mechanism having a side-facing camera 755 for capturing images of the tested device 10 mounted on the OPnP 700, and a prism 757 for facilitating image capturing by the camera 755. As will be described in more detail below, because the OPnP vision mechanism 750 detects test markings on the device 10 in order to establish the contactor array 500 position, a relatively high resolution camera 755 is preferably used. For example, in some embodiments, the resolution of the camera 755 is about 10 times higher than the resolution of the camera 255 of the input vision mechanism 250.

The vision alignment system further includes a correction mechanism to correct misalignment of the device 10 detected by the vision mechanisms of the vision alignment system. For example, in one embodiment, a raking correction mechanism 800 may be positioned on an input-side of a wall 115 positioned between the input side 110 and the test side 130, as shown in FIG. 1B. The raking correction mechanism 800 may correct alignment of devices 10 placed in the input-side transfer mechanism 300 by adjusting the position of the device pockets 310 to match the position of the devices 10 to the contactor array 500 position.

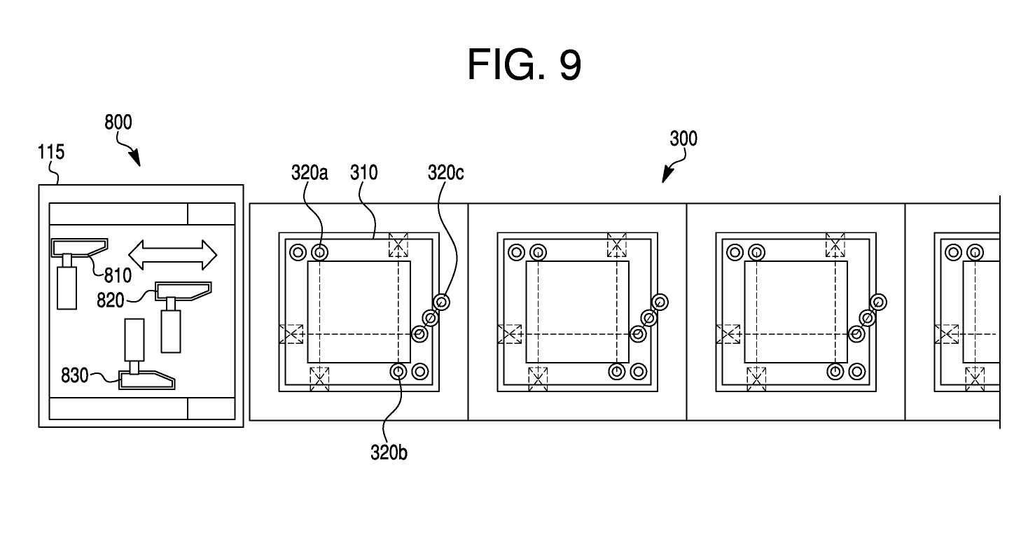

As shown in FIG. 9, the raking correction mechanism 800 includes at least three linear actuators 810, 820, 830, which engage with the first and second pins 320a, 320b, and a third alignment pin 320c of the device pockets 310 as the input-side transfer mechanism 300 moves between the input side 110 and the test side 130. The overall movement of the linear actuators 810, 820, 830 determines the movement of the device pockets 310 and, thus, the position of the device 10 placed in the device pocket 310 relative to the contactor array 500. For example, the average movement of linear actuators 810, 830, which engage with the first and second pins 320a, 320b, may determine the Y-direction offset between the device 10 and the origin of the TSPnP coordinate system as defined by the first bushing 420a and the symmetrical center of fiducial 430a. In addition, the movement of linear actuator 820, which engages with the third pin 320c, may determine the X-direction offset between the device 10 and the origin of the TSPnP coordinate system. Finally, the difference in movement between linear actuators 810, 830 may determine the angular offset of the device in the TSPnP coordinate system as defined by the second bushing 420b, along with the symmetrical center of fiducial 430b.

Because the raking correction mechanism 800 utilizes linear actuators 810, 820, 830 that adjust the device pockets 310 by effectively “raking” through the alignment pins 320a, 320b, 320c as the input-side transfer mechanism 300 moves between the input side 110 and the test side 130, adjustment time of the device 10 may be made faster as the actuators are not required to extend and retract into each device pocket 310 individually. In addition, if adjustments are needed during runtime of the test handler system 100, the raking correction mechanism 800 allows for a more efficient adjustment process that reduces overall runtime handling of the device 10 during the runtime adjustment.

### The Calibration Process

The calibration process for matching the position of the device 10 to the position of the contactor array 500 comprises primarily of two steps. First, a virtual contactor position in the TSPnP coordinate system for the contactor array 500 is determined by the visual alignment system. Second, the HGA 318 for each device pocket 310 of the input-side transfer mechanism is adjusted via the first and second pins 320a, 320b by an alignment correction mechanism, such as the raking correction mechanism 800, based on a determined position offset of the device 10 with reference to the TSPnP coordinate system.

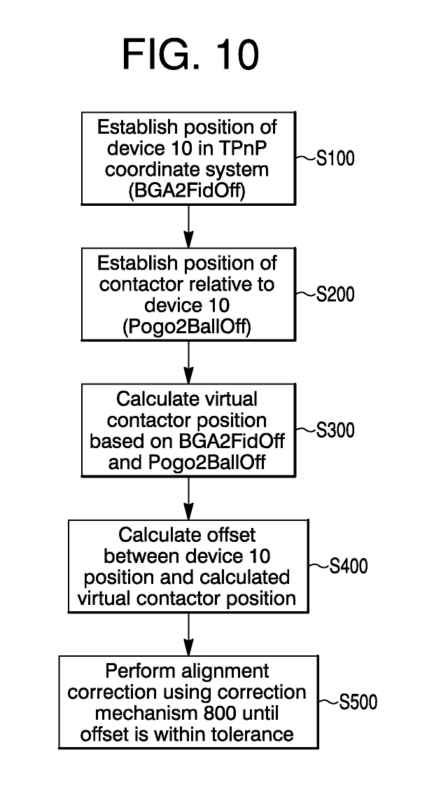

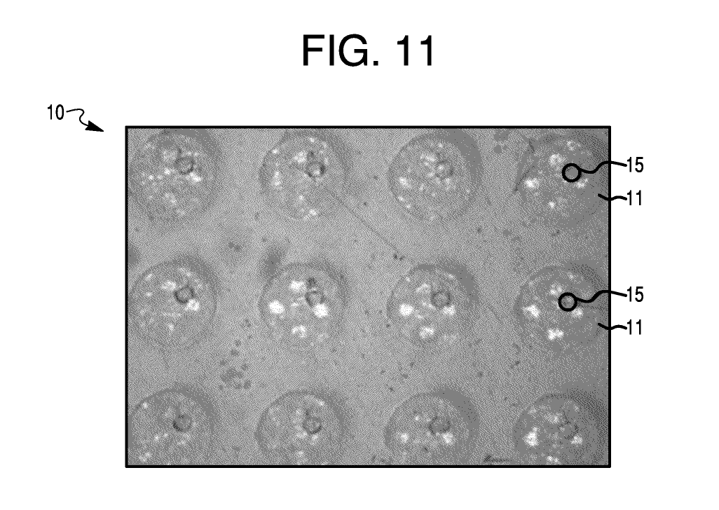

FIG. 10 shows a flowchart of a calibration process for matching or coining the device 10 to the contactor array 500 according to an embodiment of the present invention. In a step S100, a device 10 is picked up by the TSPnP 400 and imaged by the TSPnP vision mechanism 450 as the input-side transfer mechanism 300 moves from the test side 130 to the input side 110. The TSPnP vision mechanism 450 determines the angle and position of the device 10 relative to the TSPnP coordinate system as defined by the bushings 420a, 420b and stores the calculated position as “BGA2FidOff”. In other embodiments, step S100 may be performed by a TSPnP vision mechanism mounted between the input-side transfer mechanism 300 and the output-side transfer mechanism 600, after the device 10 has been tested by the contactor array 500.

In a step S200, the TSPnP 400 plunges the device 10 into the contactor array 500 to electrically test the device 10. When the TSPnP 400 plunges the device 10 into the contactor array 500, the engagement mechanisms of the TSPnP 400 (e.g., first and second bushings 420a, 420b) engage with the alignment devices disposed on the contactor array 500 (e.g., third and fourth alignment pins). During testing, the individual balls 11 in the BGA of the device 10 obtain test markings, in the form of witness marks 15 from the pogo pins of the contactor array 500 as shown in FIG. 11. In some embodiments, during the calibration process, the ball-side of the device 10 may be covered by a thin, transparent tape in order to better image the test markings. The device 10 is then transferred to the output side 120 where the OPnP vision mechanism 750 images the tested device 10 with the test markings to determine the amount of offset between the symmetrical center of the BGA ball 11 of the device 10 and its respective witness mark 15. The vision alignment system stores this calculated offset as “Pogo2BallOff”.

In a step S300, the virtual contactor array 500 position in terms of the TSPnP coordinate system is calculated by the vision alignment system based on the sum of the values calculated in steps S100 and S200 above (i.e., Pogo2BallOff+BGA2FidOff). By utilizing the TSPnP vision mechanism 450 and the OPnP vision mechanism 750, the position of the contactor array 500 may be determined outside of the test side 130 and in terms of the TSPnP coordinate system.

In a step S400, an offset between the position of the device 10 and the calculated virtual contactor array 500 position is determined. To determine the offset, the device 10 is first received into the HGA 318 of the device pocket 310 using the vacuum system to precisely align the device 10 relative to the alignment pins 320a, 320b. When the vacuum system determines that a threshold pressure has been reached by virtue of the device 10 being precisely aligned with the HGA 318, the vacuum system may be configured to alert the vision alignment system that the device 10 is properly placed, allowing the calibration process to proceed. In some embodiments, if the vacuum system determines that the threshold pressure has not been reached, the vision alignment system may be configured to stop the alignment process and alert the user that the threshold pressure has not been reached. A corrective action may then be performed such as, for example, allowing the user to manually place the device in the device pocket 310 to resume the alignment process.

Once the devices 10 have been placed within the device pockets 310, the input-side transfer mechanism 300 moves from the input side 110 to the test side 130, where the TSPnP 400 picks up a device 10 from each device pocket 310 and holds it directly over the input-side transfer mechanism 300. As the input-side transfer mechanism 300 moves from the test side 130 back to the input side 110, the TSPnP vision mechanism 450 images the device 10 on the TSPnP 400. The images are then processed and the offset of the device 10 from the virtual contactor array 500 position relative to the TSPnP coordinate system is established.

In a step S500, the offset calculated in step S400 is used by the vision alignment system to guide the alignment correction mechanism, such as the raking correction mechanism 800. In this step, as the input-side transfer mechanism 300 moves between the input side 110 and the test side 130, the raking mechanism 800 “rakes” through the pins 320a, 320b, 320c to correct for the calculated device 10 offset, as described above. The process is repeated until the device 10 is positioned to an offset less than a predetermined tolerance. Once the device 10 is aligned, the device pocket 310 is locked in placed, thus “coining” the position of the device 10 to the position of the contactor array 500.

It should be noted that the above correction process using the alignment correction mechanism presupposes linear motion of the actuators in correcting for the device 10 offset detected by the vision alignment system. However, non-linear motion of the actuators may occur instead, introducing error into the correction process. Thus, the error introduced by the non-linear motion of the actuators may be linearized in order to increase accuracy of the alignment system.

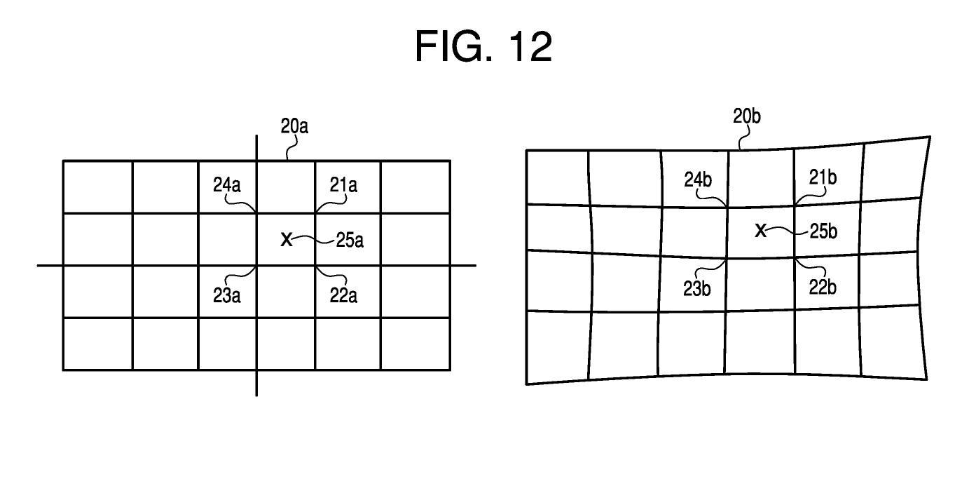

To linearize non-linear error of the alignment system, an imaged non-linear grid motion of the actuator may be mapped to an expected linear grid motion based on actuator counts. FIG. 12 shows an example of an expected linear grid motion 20a of the actuators and an imaged non-linear grid motion 20b of the actuators during the calibration process. At each node of the grids 20a, 20b, a one-to-one mapping may be used. For example, to estimate a point 25b (defined by X′,Y′), a piecewise linear transform that maps four nodes 21b, 22b, 23b, 24b of the non-linear grid (defined by X′₁, Y′₁, X′₂, Y′₂ . . . ) to the corresponding nodes 21a, 22a, 23a, 24a of the expected linear grid (defined by X₁, Y₁, X₂, Y₂ . . . ) may be used. The eight-degree transform function may then be expressed as equation (1) as follows:

$${X}^{′} = \frac{( AX + CY + E )}{( 1 - GX - HY )}$$

$${Y}^{′} = \frac{( BX + DY + F )}{( 1 - GX - HY )}$$

The above can be further written as equation (2) as follows:

X′=GX′X+HX′Y+AX+CY+E

Y′=GY′X+HY′Y+BX+DY+F

By referencing the four nodes of the linear grid 20a and the non-linear grid 20b, the linear transforms (A, B, C, D, E, F, G, H) can be determined by expressing the above equation in matrix form as equation (3):

$$[ \begin{matrix}{X}_{1}^{′} \\ {X}_{2}^{′} \\ {X}_{3}^{′} \\ {X}_{4}^{′} \\ {Y}_{1}^{′} \\ {Y}_{2}^{′} \\ {Y}_{3}^{′} \\ {Y}_{4}^{′}\end{matrix} ] = [ \begin{matrix}{X}_{1} & 0 & {Y}_{1} & 0 & 1 & 0 & {X}_{1}^{′} {X}_{1} & {X}_{1}^{′} {X}_{1} \\ {X}_{2} & 0 & {Y}_{2} & 0 & 1 & 0 & {X}_{2}^{′} {X}_{2} & {X}_{2}^{′} {Y}_{2} \\ {X}_{3} & 0 & {Y}_{3} & 0 & 1 & 0 & {X}_{3}^{′} {X}_{3} & {X}_{3}^{′} {Y}_{3} \\ {X}_{4} & 0 & {Y}_{4} & 0 & 1 & 0 & {X}_{4}^{′} {X}_{4} & {X}_{4}^{′} {Y}_{4} \\ 0 & {X}_{1} & 0 & {Y}_{1} & 0 & 1 & {Y}_{1}^{′} {X}_{1} & {Y}_{1}^{′} {Y}_{1} \\ 0 & {X}_{2} & 0 & {Y}_{2} & 0 & 1 & {Y}_{2}^{′} {X}_{2} & {Y}_{2}^{′} {Y}_{2} \\ 0 & {X}_{3} & 0 & {Y}_{3} & 0 & 1 & {Y}_{3}^{′} {X}_{3} & {Y}_{3}^{′} {Y}_{3} \\ 0 & {X}_{4} & 0 & {Y}_{4} & 0 & 1 & {Y}_{4}^{′} {X}_{4} & {Y}_{4}^{′} {Y}_{4}\end{matrix} ] [ \begin{matrix}A \\ B \\ C \\ D \\ E \\ F \\ G \\ H\end{matrix} ]$$

Once the linear transforms are determined using the above matrix equation, a point within the four-node grid space of the non-linear grid 20b may be estimated using point matching with the four-node grid space of the linear grid 20a as shown in equation (1) above. Estimation error in the above transform may be controlled by the sizes of the grids defined by the four nodes, where the smaller the individual grid, the smaller the given error.

### Runtime Adjustments Using the Vision Alignment System

Although the vision alignment and correction system described above may be used to match and lock the position of the device 10 to the position of the contactor array 500 during calibration such that continual runtime adjustment of the device 10 is not needed, the vision alignment and correction system may nevertheless be used to correct for alignment drift during runtime due to mechanical errors that may be present in the test handler system (e.g., thermal drift, mechanical wear, etc.).

For example, during runtime, as devices 10 are picked up from the input-side transfer mechanism 300 by the TSPnP 400, the TSPnP vision mechanism 450 may image the device 10 on the TSPnP 400 on-the-fly as the transfer mechanism 300 moves back to the input side 110. The images may be processed to determine if drifting from the virtual contactor array 500 position, calculated during calibration, has occurred and whether the detected drift exceeds a predetermined tolerance. If the detected drift exceeds the predetermined tolerance, the system may alert the user to the need for correction. In addition, the correction mechanism, such as the raking correction mechanism 800, may be used to correct the drift during runtime. In other embodiments, a down-looking contactor vision mechanism 550 (shown, for example, in FIG. 1B) may be added to the vision alignment system to monitor contactor array 500 drift during runtime.

Although the above embodiment of the vision alignment and correction system was described using a BGA device, the vision alignment and correction system may be used to align other fine pitch IC devices, such as LGA devices, with slight modifications.

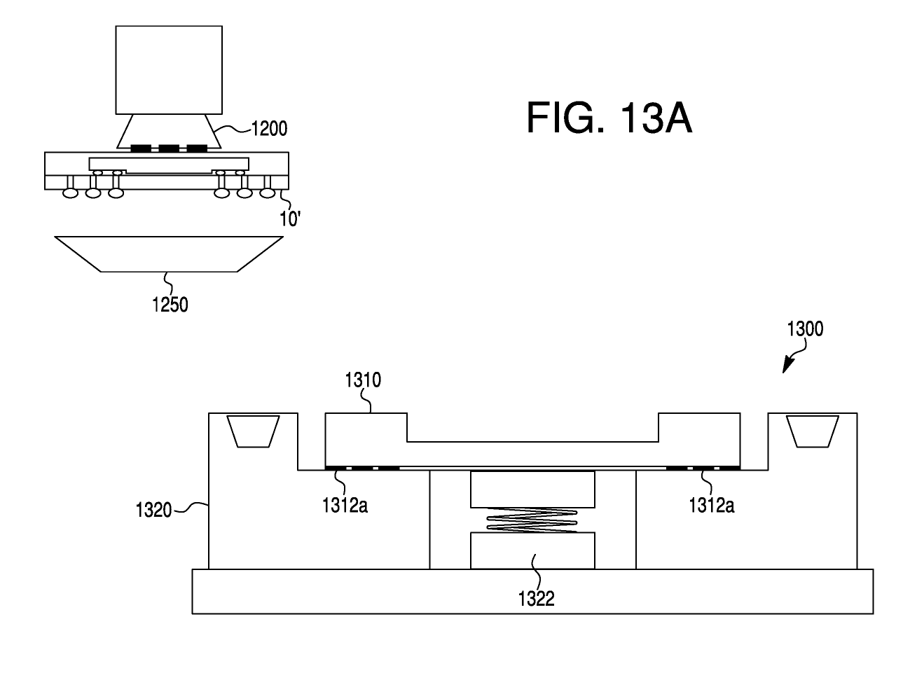

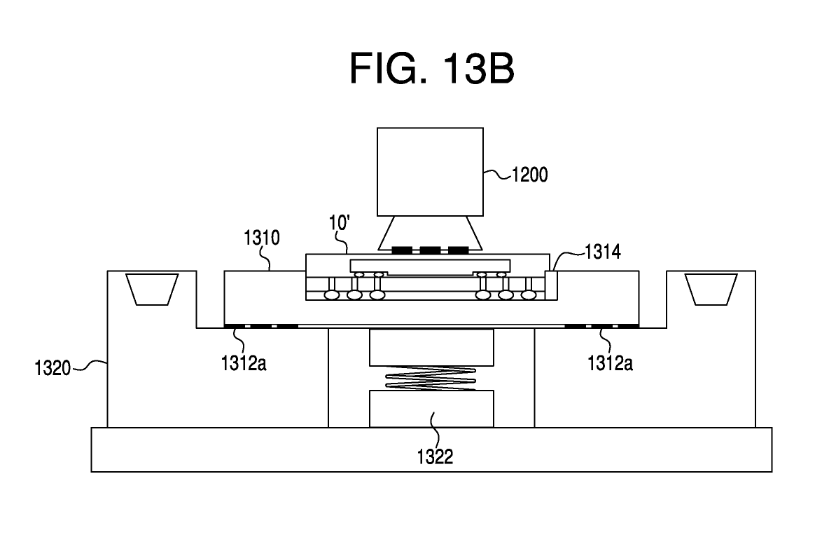

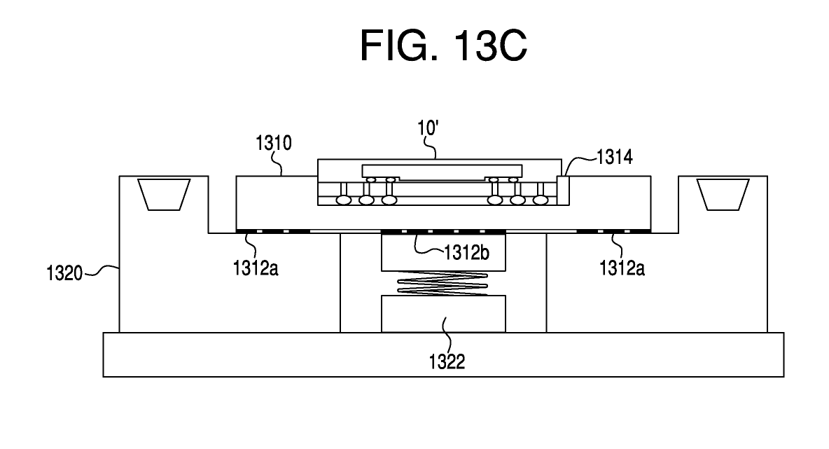

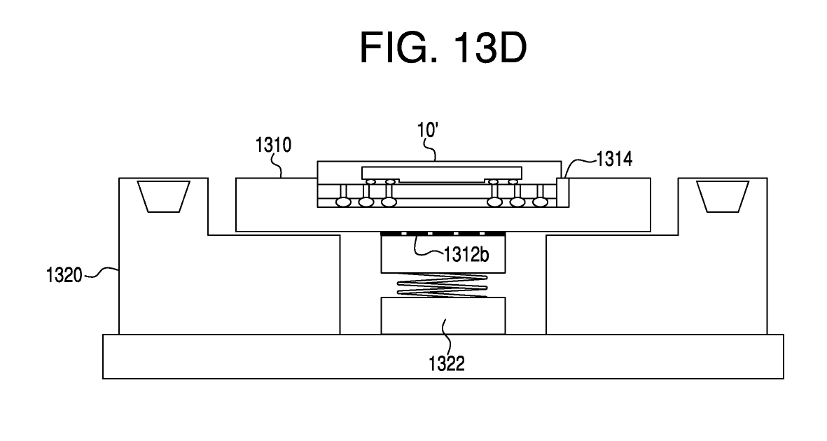

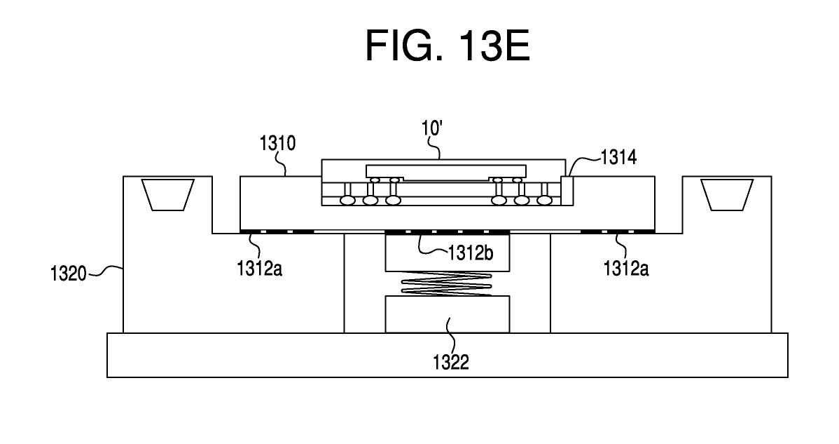

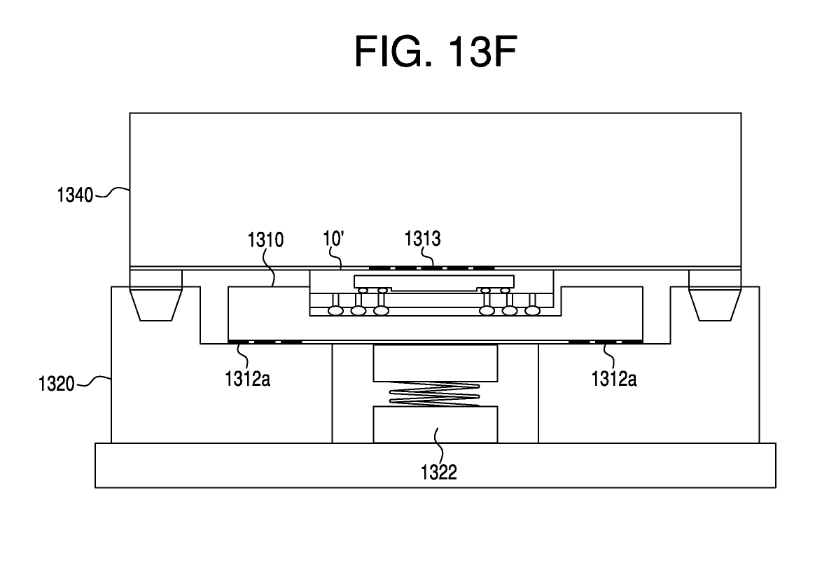

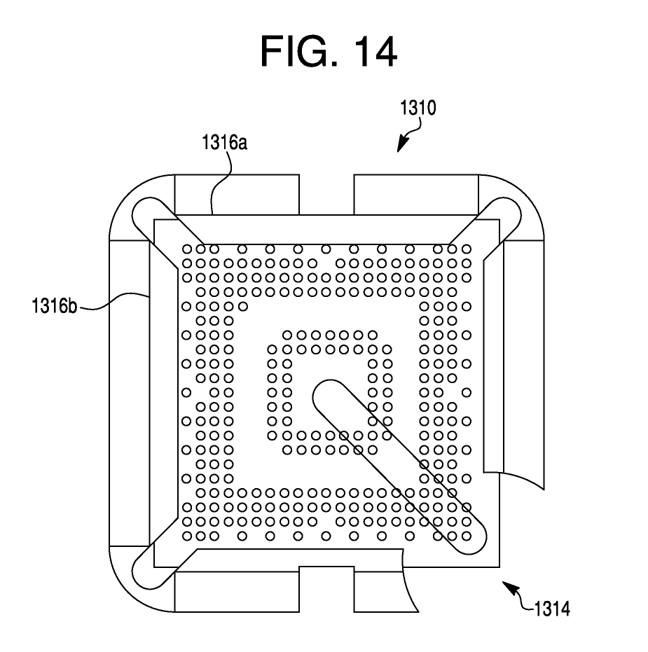

For example, FIGS. 13A-13E illustrate an alignment process using the vision alignment and correction system for an LGA device 10′ according to one embodiment. As shown in FIGS. 13A-13E, the visional alignment and correction system may include an IPnP 1200 for transferring the device 10′ from the input side to a transfer mechanism 1300 and an input vision mechanism 1250, which, like the input vision mechanism 1250, which, like the input vision mechanism 250, may be an up-looking camera positioned on the input side of the test handler system. The transfer mechanism 1300 may generally include a device pocket 1310, a base 1320 and a spring mount 1322 configured to hold the device pocket 1310, and a vacuum system configured to apply a vacuum pressure 1312a, 1312b to the device pocket 1310. In addition, an edge precisor 1314 (for example, as shown in FIG. 14) may be placed within the device pocket 1310 to precisely align the device 10′ within the device pocket 1310.

As shown in FIG. 13A, the process begins when the IPnP 1200 picks up the device 10′ and moves the device 10′ over the input vision mechanism 1250. As the IPnP 1200 moves the device 10′ over the input vision mechanism 1250, the input vision mechanism 1250 locates outer leading edges 1316a, 1316b (for example, as shown in FIG. 14) of the device 10′ mounted on the IPnP 1200. By locating the outer leading edges 1316a, 1316b of the device 10′, the vision alignment system may determine the offset of the device 10′ relative to the contactor array 500 based on the edge offsets measured during the calibration process.

As shown in FIG. 13B, the IPnP 1200 then moves the device 10′ for placement in the device pocket 1310 of the transfer mechanism 1300. With the edge precisor 1314 in place in the device pocket 1310, the outer leading edges 1316a, 1316b of the device 10′ may be précised to corresponding leading edges of the device pocket 1310. In addition, as further shown in FIG. 13B, when the IPnP 1200 places the device 10′ in the device pocket 1310, the vacuum system may apply a first vacuum pressure 1312a through the base 1320 such that the device pocket 1310 is held in place on the base 1320, thereby compressing the spring mount 1322 and facilitating placement of the device 10′ in the device pocket 1310 relative to the base 1320.

As shown in FIG. 13C, the vacuum system then applies a second vacuum pressure 1312b through the spring mount 1322 such that the device pocket 1310 is locked relative to the spring mount 1322. Once the device pocket 1310 is locked to the spring mount 1322, the vacuum system then releases the first vacuum pressure 1312a, as shown in FIG. 13D. This allows the spring mount 1322 to be released from compression and slightly displace upward, which allows the device pocket 1310 to float above the base 1320. The base 1320 may then be adjusted using a correction mechanism, such as the raking correction mechanism 800 described above, based on the calculated offset determined by the input vision mechanism 1250.

Once positioned, the vacuum system may then apply the first vacuum pressure 1312a in order to lock the device pocket 1310 and the device 10′ in place relative to the corrected base 1320, after which the second vacuum pressure 1312b may be released. The process may be repeated for each device pocket 1310 present on the transfer mechanism 1300 until all device positions are aligned. As shown in FIG. 13F, a thermal head 1340 may be lowered, which applies a vacuum pressure 1313 to the device 10′ allowing the edge precisor 1314 to be removed. Runtime adjustment may then be performed with continual monitoring by the input vision mechanism 250, while the raking correction mechanism 800 corrects the difference between the measured runtime array position and the saved device edge offset from calibration.

In addition, alternative correction mechanisms may be used in the above embodiments of the vision alignment and correction system. For example, a micro-alignment correction system as described in U.S. patent application Ser. No. 14/329,172, which is incorporated herein by reference in its entirety, may be utilized in place of the raking correction mechanism 800.

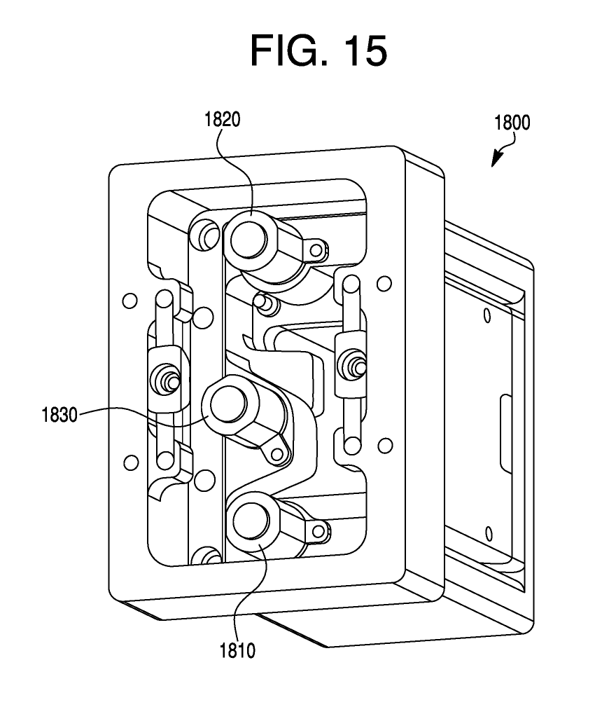

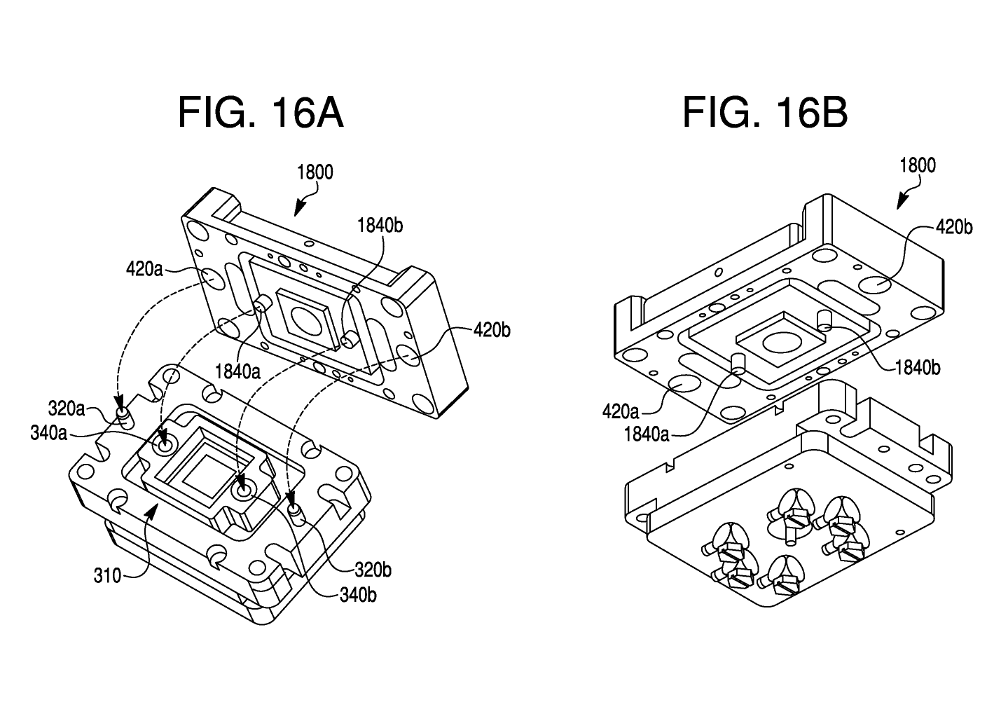

If runtime adjustments are not needed in the test handler system 100, a correction mechanism 1800, shown in FIGS. 15 and 16A-16B, may be used. As shown in FIG. 15, the correction mechanism 1800 includes three linear actuators 1810, 1820, 1830, built into an alignment head of the TSPnP 400, which are configured to correct for translation and rotation offsets of the device 10 in relation to the TSPnP coordinate system. The average movement of actuators 1810, 1820 may determine the X-direction offset between the device 10 and the origin of the TSPnP coordinate system as defined by the first bushing 420a and the symmetrical center of fiducial 430a. The movement of actuator 1830 may determine the Y-direction offset between the device and the origin of the TSPnP coordinate system as defined by the first bushing 420a and the symmetrical center of fiducial 430a. Finally, the difference in movement between actuators 1810, 1820 may determine the angular offset of the device in the TSPnP coordinate system as defined by the second bushing 420b, along with the symmetrical center of fiducial 430b.

As shown in FIGS. 16A-16B, to correct the alignment of the device 10 relative to the contactor array 500, the alignment head engages the device pocket 310 via the alignment pins 320a, 320b on the transfer mechanism 300 through bushings 420a, 420b, in order to define the common local coordinate system. In addition, adjustment pins 1840a, 1840b are provided on the alignment head that engage with adjustment bushings 340a, 340b on the device pocket 310. When the alignment head engages with the transfer mechanism 300 and the device pocket 310 through the pin-bushing engagement, the linear actuators 1810, 1820, 1830 move to adjust the device pocket 310 in order to correct for any offset calculated between the device 10 and the contactor array 500.

The simplicity of the vision alignment system allows for an ease in changing a conventional test handler system from a mechanical alignment system to a vision alignment system. For example, present alignment systems may use the mechanical contactor socket array as a means for vision alignment. In the vision alignment system of the present disclosure, however, no changes are needed to the contactor test site since the vision alignment process may be performed substantially off-site and offline. In addition, for the TSPnP and IPnP equipment, fiducials may be placed on the PnP devices without the need for additional actuators on the PnP devices. Because equipment for the vision alignment system are substantially placed outside of the test side region, equipment placed at the test site is minimized, making upgrading to the vision alignment system easier due to available increased space. Finally, little to no runtime adjustment is needed once the vision alignment process has been performed during calibration because positions of both the device and the contactor array have been matched and locked into place during the calibration process. The vision alignment system of the present disclosure allows for an improved accuracy of mechanical alignment systems present in the test handler system.

While the preferred embodiments of the devices and methods have been described in reference to the environment in which they were developed, they are merely illustrative of the principles of the inventions. Modification or combinations of the above-described assemblies, other embodiments, configurations, and methods for carrying out the invention, and variations of aspects of the invention that are obvious to those of skill in the art are intended to be within the scope of the claims.

What is claimed is:

1. A vision alignment system for an integrated circuit device test handler system comprising:
a transfer mechanism configured to transfer an integrated circuit device from an input side to a test side of the test handler system, the transfer mechanism comprising a first alignment device;
a contactor array positioned at the test side and configured to electrically test the integrated circuit device, the contactor array comprising a second alignment device;
a test pick-and-place device configured to move the integrated circuit device from the transfer mechanism to the contactor array, the test pick-and-place device comprising a first engagement mechanism configured to engage with the first alignment device and the second alignment device;
a first vision mechanism positioned at the input side and configured to determine a position of the integrated circuit device relative to a common local coordinate system;
a second vision mechanism positioned at an output side of the test handler system and configured to determine a position of the contactor array relative to the common local coordinate system; and
a correction mechanism configured to correct a position of the integrated circuit device placed on the transfer mechanism based on a calculated offset between the position of the integrated circuit device and the position of the contactor array in the common local coordinate system.

2. The vision alignment system of claim 1, wherein an engagement between the first engagement mechanism of the test pick-and-place device and the first alignment device of the transfer mechanism and an engagement between the first engagement mechanism of the test pick-and-place device and the second alignment device of the contactor array define the common local coordinate system among the test pick-and-place device, the transfer mechanism, the contactor array, and the correction mechanism.

3. The vision alignment system of claim 1, wherein the first vision mechanism is mounted on the transfer mechanism.

4. The vision alignment system of claim 3, wherein the first vision mechanism is configured to image the test pick-and-place device as the transfer mechanism moves from the test side to the input side of the test handler system.

5. The vision alignment system of claim 1, wherein the test pick-and-place device further comprises a second engagement mechanism, the first engagement mechanism defining an origin of the common local coordinate system and the second engagement mechanism defining a rotation in the common local coordinate system.

6. The vision alignment system of claim 5, wherein the transfer mechanism further comprises a third alignment device, and wherein the first alignment device is a first pin configured to engage with the first engagement mechanism and the third alignment device is a second pin configured to engage with the second engagement mechanism.

7. The vision alignment system of claim 5, wherein the first engagement mechanism is a first bushing mounted on a head of the test pick-and-place device and the second engagement mechanism is a second bushing mounted on the head of the pick-and-place device.

8. The vision alignment system of claim 7, wherein the first bushing comprises a main body and an origin-establishing extension that extends from the main body and includes a central groove in the form of a half circle.

9. The vision alignment system of claim 7, wherein the second bushing comprises a main body and a rotation-establishing extension that extends from the main body and includes a flat surface.

10. The vision alignment system of claim 5, wherein the test pick-and-place device further comprises a first fiducial positioned between the first bushing and a first side of the integrated circuit device when mounted on the test pick-and-place device and a second fiducial positioned between the second position and a second side of the integrated circuit device.

11. The vision alignment system of claim 1, wherein the integrated circuit device is a ball grid array device.

12. The vision alignment system of claim 11, wherein the transfer mechanism comprises a device pocket comprising a hole grid array formed on a bottom surface of the device pocket, the hole grid array being configured to receive the ball grid array device.

13. The vision alignment system of claim 12, wherein the transfer mechanism further comprises a vacuum system configured to apply a vacuum pressure to the hole grid array such that the ball grid array device is precisely aligned in the hole grid array.

14. The vision alignment system of claim 13, wherein the vacuum system is configured to detect when a pressure threshold is reached after applying the vacuum pressure to the hole grid array.

15. The vision alignment system of claim 12, wherein the device pocket further comprises chamfered edges formed peripherally along an upper portion of the device pocket, the chamfered edges being angled such that placement of the integrated circuit device in the device pocket is facilitated by the chamfered edges.

16. The vision alignment system of claim 6, wherein the correction mechanism is configured to correct the position of the integrated circuit device by adjusting positions of the first pin and the second pin.

17. The vision alignment system of claim 1, further comprising:
an input pick-and-place device, the input pick-and-place device configured to place the integrated circuit device on the transfer mechanism; and
an input vision mechanism, the input vision mechanism configured to determine a position of the integrated circuit device relative to the input pick-and-place device and correct a placement of the integrated circuit device on the transfer mechanism.

18. The vision alignment system of claim 1, wherein the correction mechanism comprises a plurality of actuators configured to correct the position of the integrated circuit device placed on the transfer mechanism as the transfer mechanism transfers the integrated circuit device from the input side to the test side.

19. The vision alignment system of claim 1, wherein the correction mechanism comprises a micro-alignment system comprising:
a head guiding ring configured to be attached to the test pick-and-place device; and
a socket apparatus comprising a fixed mounting frame having an opening in which the contactor array is locatable, a moveable socket guiding ring having an opening in which the head guiding ring is locatable, and a plurality of actuators configured to move the moveable socket guiding ring relative to the fixed mounting frame,
wherein the socket apparatus is configured to adjust a position of the head guiding ring by moving the moveable socket guiding ring while the head guiding ring is located in the opening of the moveable socket guiding ring to align the integrated circuit device to the contactor array.

20. A method for visually aligning an integrated circuit device in a test handler system, comprising:
moving an integrated circuit device using a transfer mechanism from an input side of the test handler system to a test side of the test handler system, the transfer mechanism comprising a first alignment device;
moving the integrated circuit device from the transfer mechanism to a contactor array using a pick-and-place device, the test pick-and-place device comprising a first engagement mechanism;
imaging the integrated circuit device on the pick-and-place device;
calculating a position of the integrated circuit device relative to a local coordinate system;
testing the integrated circuit device using the contactor array, the contactor array comprising a second alignment device and the tested integrated circuit device having a plurality of test markings;
imaging the tested integrated circuit device at an output side of the test handler system;
calculating a position of the contactor array relative to the local coordinate system based on positions of the plurality of test markings and the relative position of the integrated circuit device;
determining an offset between the calculated position of the integrated circuit device and the calculated position of the contactor array relative to the local coordinate system; and
correcting a position of the integrated circuit device placed on the transfer mechanism based on the determined offset using a correction mechanism.

21. The method of claim 20, wherein an engagement between the first engagement mechanism of the pick-and-place device and the first alignment device of the transfer mechanism and an engagement between the first engagement mechanism of the pick-and-place device and the second alignment device of the contactor array define the local coordinate system among the pick-and-place device, the transfer mechanism, the contactor array, and the correction mechanism.

22. The method of claim 20, further comprising:
monitoring a change in the position of the integrated circuit device placed on the transfer mechanism during a testing of the integrated circuit device; and
correcting the change in the position of the integrated circuit device placed on the transfer mechanism.

23. The method of claim 20, wherein the integrated circuit device is a ball grid array device.

24. The method of claim 22, wherein the transfer mechanism comprises a device pocket having a hole grid array at a bottom surface configured to receive the ball grid array device.
